(19) United States
(12) Patent Application Publication
(10) Pub. No.: US 2022/0247967 A1
(43) Pub. Date: Aug. 4, 2022

(54) IMAGE SENSOR

(71) Applicant: TECH IDEA CO., LTD., Kanagawa (JP)

(72) Inventors: Akira MATSUZAWA, Kanagawa (JP); Lilan YU, Kanagawa (JP)

(21) Appl. No.: 17/616,184

(22) PCT Filed: Sep. 18, 2020
(86) PCT No.: PCT/JP2020/035412

§ 371 Date: Dec. 3, 2021

(30) Foreign Application Priority Data
Sep. 26, 2019 (JP) 2019-175854

(51) Int. Cl. H04N 5/3745; H03M 1/56; H04N 5/378

(52) U.S. Cl. CPC H04N 5/37455; H04N 5/378; H03M 1/56

(57) ABSTRACT

An image sensor that operates at high speed and high accuracy with low power consumption. A CMOS image sensor includes: a pixel unit including a plurality of pixels two-dimensionally arranged in a row direction and a column direction, each of the plurality of pixels including a sensor element configured to detect a physical amount existing in nature and to convert the physical amount into an electric signal; a resistance type digital-to-analog converter including a plurality of unit circuits connected in parallel to one another and configured to generate a ramp wave, each of the plurality of unit circuits including a resistor connected to an output end of a CMOS inverter; and an analog-to-digital conversion unit including a plurality of integral type analog-to-digital converters and configured to convert signals from the pixels into digital signals by comparing the signals from the pixels with the ramp wave.

### CROSS-REFERENCE TO RELATED APPLICATIONS

The present application is a National Phase of International Application No. PCT/JP2020/035412 filed Sep. 18, 2020, which claims the benefit of priority from the prior Japanese patent application No. 2019-175854 filed on Sep. 26, 2019, the entire contents of which are incorporated herein by reference.

### TECHNICAL FIELD

The present invention relates to an image sensor.

### BACKGROUND ART

As a conventional representative image sensor, there is a complementary metal oxide semiconductor (CMOS) image sensor. FIG. 15 is a block diagram illustrating a configuration of a conventional CMOS image sensor. As illustrated in FIG. 15, in a conventional CMOS image sensor 100, pixels 101a are two-dimensionally arranged in a horizontal direction and a vertical direction in a pixel unit 101, and a vertical control circuit 102 selects the pixels 101a of an arbitrary row by setting one of row access lines 103 to “H”.

The pixels 101a in the selected row simultaneously output voltages corresponding to brightness of the respective pixels. The voltages are input to a plurality of integral type analog-to-digital converters (hereinafter, analog-to-digital conversion is referred to as A/D conversion, and A/D converter is illustrated as ADC in drawings) of an A/D conversion unit 105 through pixel signal lines 104. The voltages are converted into digital signals by the A/D conversion unit 105, and the digital signals are output from an output terminal through a horizontal control circuit 106.

The A/D conversion is normally performed by an integral type A/D converter that counts the number of clocks by using a ramp wave generated by a current type digital-to-analog converter (hereinafter, digital-to-analog conversion is referred to as D/A conversion, and D/A converter is illustrated as DAC in drawings) and a counter. FIG. 16 is a circuit diagram illustrating a basic configuration of the integral type A/D converter used for the CMOS image sensor, and FIG. 17 is a diagram illustrating a waveform of a ramp wave input to the A/D converter.

As illustrated in FIG. 16, in a case where the A/D conversion is performed by the integral type A/D converter, switches S between input and output of a comparator 111 are first closed. At this time, a standard voltage V_{in_0} is applied as an input voltage Vᵢₙ. Normally, the standard voltage on a pixel side is applied to a gate of a source follower in the pixel 101a, and a voltage of a source is set to V_{in_0}. At this time, a standard output voltage of the D/A converter is applied as a reference voltage V_{ref}. In such a state, the switches S are opened and the comparator 111 receives the signal from the pixel 101 in which brightness is reflected on an input voltage Vᵢₙ.

Next, the D/A converter is controlled to generate a ramp wave falling as illustrated in FIG. 17. A counter 112 is first reset, and then starts to count the number of clocks in response to application of a clock signal. When a difference between the input standard voltage and the input voltage Vᵢₙ is coincident with a difference signal between the standard voltage of the D/A converter and the reference voltage V_{ref}, an output of the comparator 111 is inverted and the counter 112 stops, and a count value at this time is output as an A/D conversion value. In many cases, to secure conversion accuracy for a feeble signal, the reference voltage V_{ref} falls from a voltage once raised by V_{off} from the standard voltage of the D/A converter. A time obtained by subtracting an offset time T_{off} from a conversion time T_{c} is proportional to the input voltage Vᵢₙ. Therefore, the A/D conversion value of the input voltage Vᵢₙ can be obtained by using the conversion time T_{c}.

The integral type A/D converter used for the image sensor needs the ramp wave, and the ramp wave is often generated by the D/A converter (for example, see Patent Literatures 1 to 3 and Non Patent Literature 1). FIG. 18 is a circuit diagram illustrating a configuration of a current type D/A converter used for the conventional CMOS image sensor. As illustrated in FIG. 18, the conventional representative current type D/A converter includes a plurality of unit current sources 122.

The current type D/A converter controls a value of a current flowing through a load resistor 124 by using switches 123 controlled by input signals decoded by a decoder 121, to switch a flowing direction of the current to the load resistor 124 side or a power supply 125 side, thereby generating a voltage on the load resistor 124. Further, the current flowing through the load resistor 124 is sequentially increased with time to obtain a ramp wave as an output.

### CITATION LIST

### Patent Literature

Patent Literature 1: International Publication No. WO 2013/122221
Patent Literature 2: Japanese Patent Application No. 2013-239951
Patent Literature 3: Japanese Patent Application No. 2018-148541

### Non Patent Literature

Non Patent Literature 1: S. Yoshihara, et al., “A 1/1.8-inch 6.4 MPixel 60 frames/s CMOS Image Sensor With Seamless Mode Change”, IEEE Journal of Solid-State Circuits, December 2006, Vol. 41, No. 12, pp. 2998-3006

### SUMMARY OF INVENTION

### Technical Problem

The above-described conventional current type D/A converter, however, has issues described below. A first issue is power consumption. FIG. 19 is a circuit diagram illustrating a configuration of a unit current source of the current type D/A converter. As illustrated in FIG. 19, the unit current source of the current type D/A converter includes a transistor M₁ determining a current value, a cascode transistor M₂ increasing constant current property to improve linearity, and transistors M₃ and M₄ functioning as switches switching a current path.

In the case of the CMOS image sensor, a voltage amplitude Vₛ of the output voltage Vast is up to about 1.2 V. Each of drain-source voltages V_{DS1} and V_{DS2} of the transistors M₁ and M₂ is required to be at least 0.3 V because the transistors M₁ and M₂ are required to operate in a saturation region. Therefore, a power supply voltage V_{DD} is required to be at least 1.8 V. At this time, when a load resistance is denoted by R_{L}, a current I_{DAC} flowing through the D/A converter is represented by the following expression 1.

### [Expression 1]

Further, a power consumption P_{DAC} of the D/A converter is represented by the following expression 2.

### [Expression 2]

In recent years, a load capacity is increased due to increase of the number of pixels and increase of the number of required frames; however, it is necessary to reduce the load resistance R_{L} in order to secure a certain amount of response time constant. Therefore, the power consumption of the D/A converter tends to increase, and reduction of the power consumption is a large issue. Further, the image sensor is sensitive to temperature, and a dark current is considerably increased as operation temperature is increased. Therefore, it is highly desirable to suppress the power consumption as much as possible also in terms of image quality.

A second issue is a response speed. Insufficient time response characteristics of the D/A converter inhibits acceleration of operation of the image sensor. FIG. 20 is a diagram illustrating a waveform of a ramp wave in a case where a minute voltage section is swept a number of times. In recent years, a method in which A/D conversion is performed by sweeping a minute voltage section of about 50 mV as illustrated in FIG. 20 a plurality of times, and an average of obtained conversion values is determined to reduce conversion noise has been proposed. In this method, however, it is difficult to perform the A/D conversion a number of times within a certain time period because of insufficient time response characteristics of the D/A converter.

FIG. 21 is a diagram illustrating an ideal waveform and an actual waveform of a ramp wave generated by using the D/A converter. As illustrated in FIG. 21, when the conventional D/A converter generates the ramp wave of 50 mV by 50 ns, waveform distortion occurs, and linearity of the ramp wave is secured only in a region of 40 mV by 40 ns. Therefore, the conventional D/A converter is required to generate a ramp wave having more margin, which inhibits high-speed operation.

Therefore, an object of the present invention is to provide an image sensor that is low in power consumption and operates at high speed with high accuracy.

### Solution to Problem

To solve the above-described issues, the inventors examined the digital-to-analog converter generating the ramp wave in the image sensor. As a result, the inventors found that a resistance type digital-to-analog converter in which resistors connected to output ends of respective inverters are connected in parallel to one another is essentially low in power consumption as compared with a conventional current type digital-to-analog converter using a current source, and conceived the present invention.

An image sensor according to the present invention includes: a pixel unit including a plurality of pixels two-dimensionally arranged in a row direction and a column direction, each of the plurality of pixels including a sensor element configured to detect a physical amount existing in nature and to convert the physical amount into an electric signal; a resistance type digital-to-analog converter including a plurality of unit circuits connected in parallel to one another and configured to generate a ramp wave, each of the plurality of unit circuits including a resistor connected to an output end of a CMOS inverter; and an analog-to-digital conversion unit including a plurality of integral type analog-to-digital converters and configured to convert signals from the pixels into digital signals by comparing the signals from the pixels with the ramp wave.

The resistance type digital-to-analog converter may include a high-order bit conversion unit and a low-order bit conversion unit, the high-order bit conversion unit including the unit circuits connected in parallel to one another for number corresponding to high-order bits, each of the unit circuits of the high-order bit conversion unit including the resistor having one end connected to the output end of the CMOS inverter and another end connected to an output end of the resistance type digital-to-analog converter, the low-order bit conversion unit including the unit circuits connected in parallel to one another for number corresponding to low-order bits, each of the unit circuits of the low-order bit conversion unit including the resistor having one end connected to the output end of the CMOS inverter and another end connected to a resistor between terminals.

The CMOS inverter of the unit circuit may include a transistor having a channel length of 90 nm or less.

The resistance type digital-to-analog converter may be provided at each of both ends of a signal line supplying the ramp wave to the analog-to-digital conversion unit.

Further, the inventors analyzed a time response when the ramp wave is generated by the digital-to-analog converter, and found a method of generating the ramp wave having no waveform distortion through control of an offset voltage.

In the image sensor according to the present invention, when a time rate of change of a voltage of the ramp wave is varied, a prescribed offset value may be input to the resistance type digital-to-analog converter.

In a case where the time rate of change of the voltage of the ramp wave is varied a plurality of times with time, the offset value may be varied based on variation of the time rate of change.

Further, the offset value may be calculated based on a first standard voltage, a second standard voltage different from the first standard voltage, a first time point when the voltage of the ramp wave becomes the first standard voltage, and a second time point when the voltage of the ramp wave becomes the second standard voltage.

### Advantageous Effects of Invention

According to the present invention, since the ramp wave is generated by using the resistance type digital-to-analog converter, it is possible to largely reduce the average power consumption as compared with the current type D/A converter having the same output resistance, and to realize an image sensor that is low in power consumption and operates at high speed with high accuracy.

### BRIEF DESCRIPTION OF DRAWINGS

FIG. 1 is a block diagram illustrating a configuration of an image sensor according to a first embodiment of the present invention.

FIG. 2A is a circuit diagram illustrating a configuration example of a resistance type D/A converter 8 illustrated in FIG. 1, and FIG. 2B is a diagram illustrating an inverter 81 of the resistance type D/A converter 8.

FIG. 3 is a circuit diagram to determine a current consumption and a power consumption of the resistance type D/A converter 8 illustrated in FIG. 1.

FIG. 4 is a circuit diagram illustrating an equivalent circuit viewed from an output end of the resistance type D/A converter 8 illustrated in FIG. 1.

FIG. 5 is a graph illustrating a current consumption of a current type D/A converter and a current consumption and an average current consumption of a resistance type D/A converter, to an output voltage of a D/A converter.

FIG. 6 is a circuit diagram illustrating a D/A converter generating a ramp wave and a distributed RC circuit serving as a load.

FIG. 7 is a circuit diagram illustrating a distributed RC circuit and D/A converters driving the distributed RC circuit from both sides, in the image sensor according to the first embodiment of the present invention.

FIG. 8 is a circuit diagram illustrating an equivalent circuit of a D/A converter considering a load.

FIG. 9 is a block diagram illustrating a configuration of a resistance type D/A converter of an image sensor according to a second embodiment of the present invention.

FIG. 10 is a waveform diagram illustrating an output voltage of a resistance type D/A converter 28 illustrated in FIG. 9 and a voltage of a load circuit having a capacity, in a case where a prescribed offset value is added when a time rate of change of a voltage of a ramp wave is varied.

FIG. 11 is a waveform diagram illustrating an output voltage V_{DAC} of the resistance type D/A converter and a voltage Vₒᵤₜ of the load circuit having a capacity, in a case where no correction value is added when the time rate of change is varied twice.

FIG. 12 is a waveform diagram illustrating the output voltage of the D/A converter and the voltage of the load circuit having the capacity, in a case where a time rate of change of the ramp wave is varied a plurality of times with time and the offset value is accordingly varied when the time rate of change of the voltage of the ramp wave is varied.

FIG. 13 is a diagram illustrating a configuration of a calibration circuit.

FIG. 14 is a diagram illustrating relationship of an output voltage, a standard voltage, and a time in the calibration circuit illustrated in FIG. 13.

FIG. 15 is a block diagram illustrating a configuration of a conventional CMOS image sensor.

FIG. 16 is a circuit diagram illustrating a basic configuration of an integral type A/D converter used for the CMOS image sensor.

FIG. 17 is a diagram illustrating a waveform of a ramp wave input to the integral type A/D converter.

FIG. 18 is a circuit diagram illustrating a current type D/A converter used for a conventional CMOS image sensor.

FIG. 19 is a circuit diagram illustrating a configuration of a unit current source of the current type D/A converter.

FIG. 20 is a diagram illustrating a waveform of a ramp wave in a case where a minute voltage section is swept a number of times.

FIG. 21 is a diagram illustrating an ideal waveform and an actual waveform of a ramp wave generated by using the D/A converter.

### DESCRIPTION OF EMBODIMENTS

Some embodiments of the present invention are described in detail below with reference to accompanying drawings. Note that the present invention is not limited to the embodiments described below.

### First Embodiment

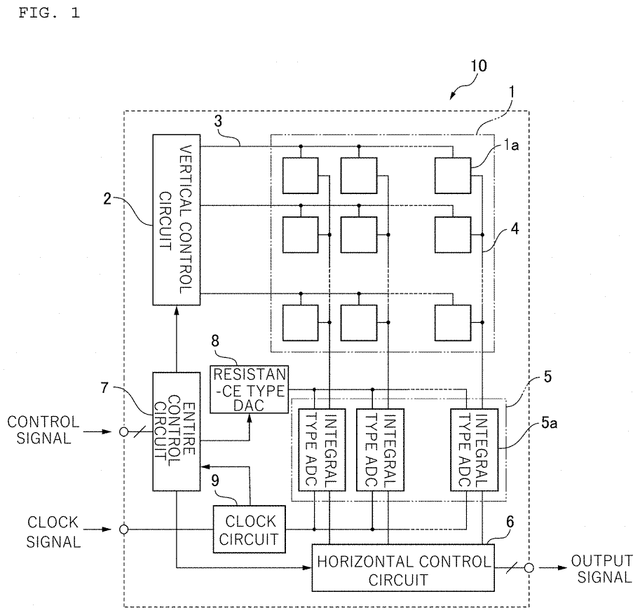

First, an image sensor according to a first embodiment of the present invention is described. FIG. 1 is a block diagram illustrating a configuration of the image sensor according to the present embodiment. As illustrated in FIG. 1, an image sensor 10 according to the present embodiment includes a pixel unit 1 including a plurality of pixels 1a, an A/D conversion unit 5 converting pixel signals into digital signals, a resistance type D/A converter 8 supplying a ramp wave as a reference voltage to the A/D conversion unit 5, and the like. Thus, the image sensor 10 according to the present embodiment uses not a current type D/A converter but the resistance type D/A converter 8 as the D/A converter generating the ramp wave to be supplied to the A/D conversion unit 5.

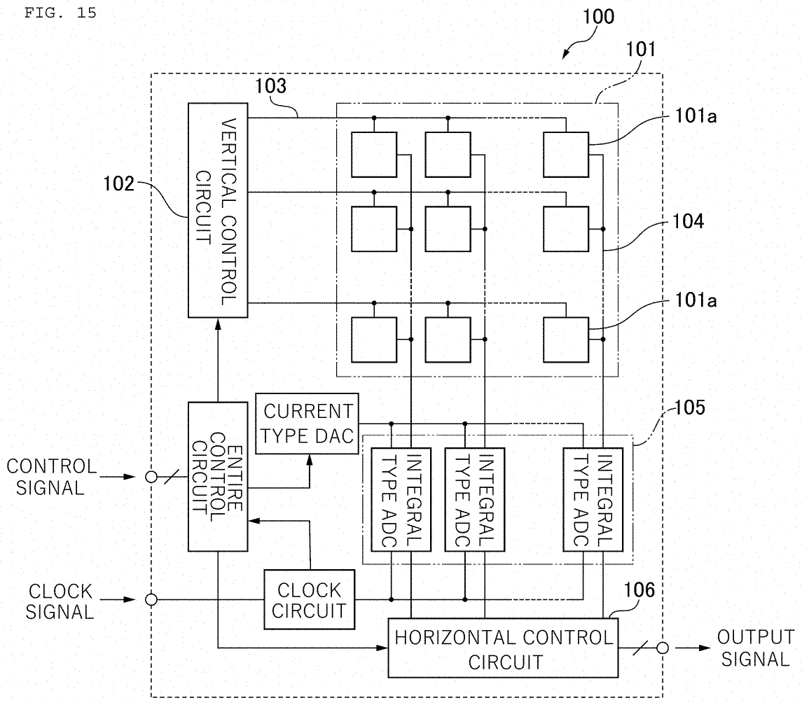

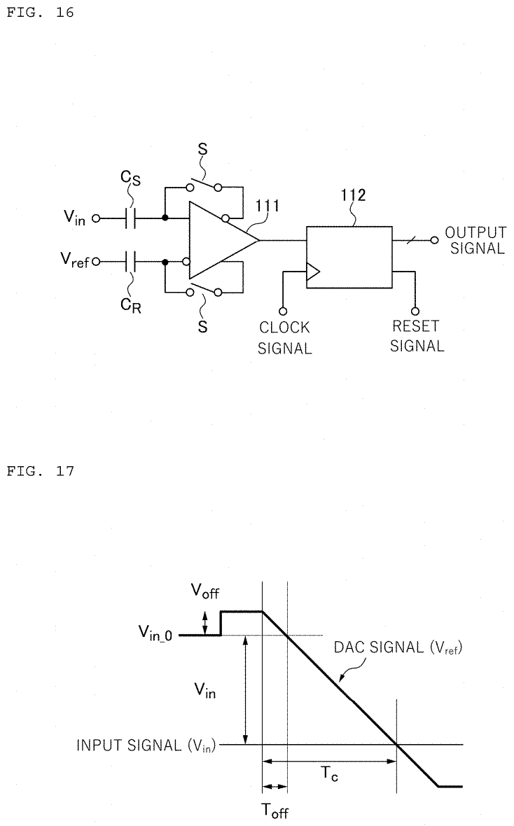

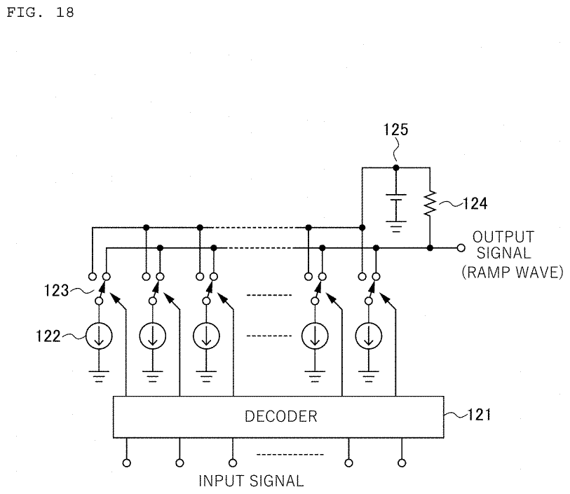

For example, as with the CMOS image sensor illustrated in FIG. 15, the image sensor 10 according to the present embodiment may further include a vertical control circuit 2 controlling row access lines 3 connected to the pixels 1a, pixel signal lines 4 connected to the pixels 1a and transmitting the pixel signals to the A/D conversion unit 5, a horizontal control circuit 6 controlling output of the digital signals generated by the A/D conversion unit 5, an entire control circuit 7, a clock circuit 9, and the like.

### [Pixel Unit 1]

In the pixel unit 1, the plurality of pixels 1a are two-dimensionally arranged in a row direction and a column direction. Each of the pixels 1a of the pixel unit 1 includes a sensor element that detects a physical amount existing in nature and converts the physical amount into an electric signal. The physical amount existing in nature includes visible light, infrared light, an ultraviolet ray, an X-ray, an electromagnetic wave, an electric field, a magnetic field, temperature, pressure, and the like.

### [A/D Conversion Unit 5]

The A/D conversion unit 5 converts the pixel signals from the respective pixels 1a of the pixel unit 1, into the digital signals by performing comparison with the ramp wave from the resistance type D/A converter 8. The A/D conversion unit 5 includes a plurality of integral type A/D converters 5a.

[Resistance type D/A Converter 8]

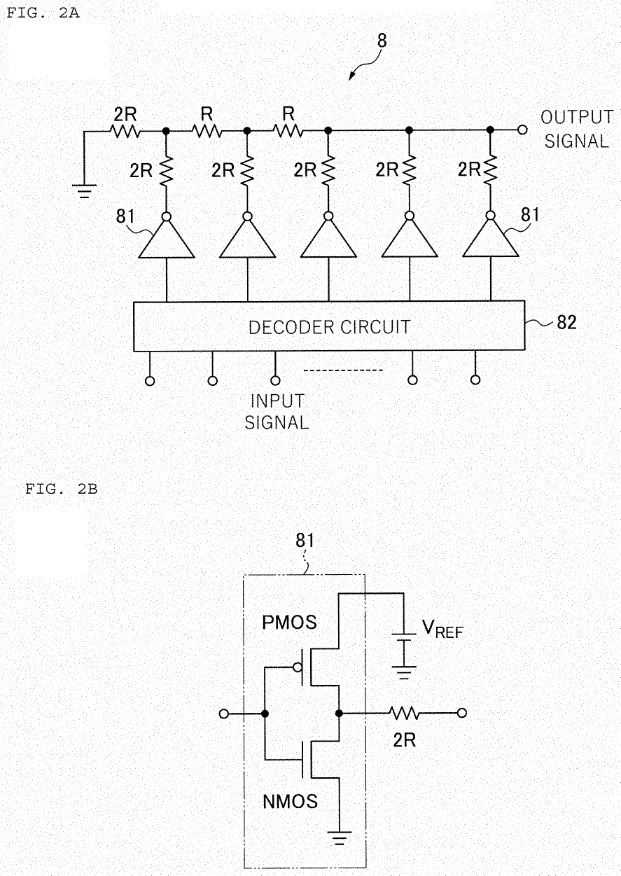

FIG. 2A is a circuit diagram illustrating a configuration example of the resistance type D/A converter 8 illustrated in FIG. 1, and FIG. 2B is a circuit diagram of an inverter 81 of the resistance type D/A converter 8. In the resistance type D/A converter 8 illustrated in FIG. 2A, unit circuits are connected in parallel to one another. In each of the unit circuits, one end of a resistor is connected to an output terminal of the inverter 81. Further, a power supply of each of the inverters 81 of the resistance type D/A converter 8 uses a reference voltage V_{REF}. In the resistance type D/A converter 8, input signals are input to a decoder circuit 82, and decoded signals are input to the inverters 81.

The resistance type D/A converter 8 includes, for example, a segment type D/A converter using a thermometer code for high-order 2 bits and a binary type D/A converter using an R-2R resistor ladder for low-order 2 bits, and operates as a 4-bit D/A converter. The segment type D/A converter configuring a high-order bit conversion unit includes unit circuits connected in parallel to one another, the number of the unit circuits corresponding to the number of high-order bits. In each of the unit circuits, the other end of the resistor is connected to an output end of the resistance type D/A converter 8.

In contrast, a low-order bit conversion unit performing conversion of low-order bits includes the binary type D/A converter using the R-2R resistor ladder. The binary type D/A converter includes unit circuits connected in parallel to one another, the number of the unit circuits corresponding to the number of low-order bits. In each of the unit circuits, one end of a resistor is connected to an output end of a CMOS inverter, and the other end of the resistor is connected to a resistor provided between terminals. In this case, an accurate output voltage can be obtained by setting resistance values to a ratio illustrated in FIG. 2A. Bit distribution between the high-order bits and the low-order bits can be appropriately set depending on an application and a specification; however, the high-order bits and the low-order bits are preferably set to the numbers of bits substantially equal to each other in terms of accuracy and an area.

As each of the inverters 81, for example, a CMOS inverter including an NMOS transistor and a PMOS transistor illustrated in FIG. 2B can be used. A transistor used for a conventional current type D/A converter is not a core transistor using a fine gate used for an internal logic, but an I/O transistor having a withstand voltage of about 3.3 V because the transistor is required to have a withstand voltage of at least 1.8 V. Therefore, the current type D/A converter is large not only in area but also in capacity, which makes it difficult to perform high-speed operation and increases the power consumption.

In contrast, the resistance type D/A converter 8 used for the image sensor 10 according to the present embodiment is required to have the transistor withstand voltage of only about 1.0 V to about 1.2 V. Therefore, for example, a fine core transistor that can minimize a channel length to 90 nm or less. As described above, the resistance type D/A converter can obtain sufficiently low on-resistance even by using a small transistor, which makes it possible to realize excellent linearity of the D/A converter. As a result, using the resistance type D/A converter makes it possible to reduce the occupied area and the power consumption of the D/A converter, and to accelerate the processing. Further, the D/A converter includes such a configuration, which makes it possible to considerably reduce the power consumption as compared with the conventional current type D/A converter.

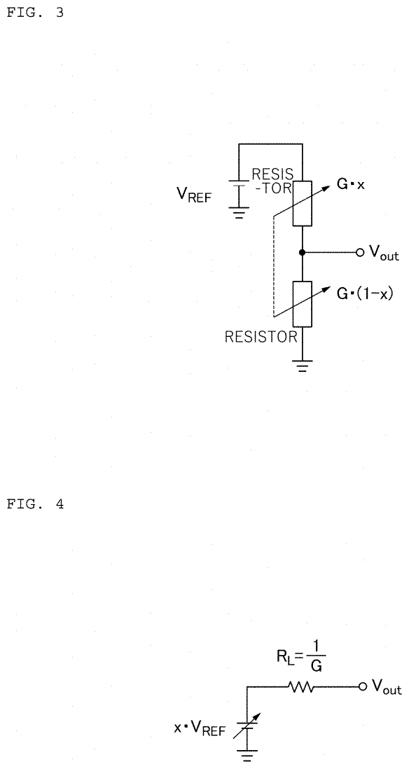

FIG. 3 is a circuit diagram to determine the current consumption and the power consumption of the resistance type D/A converter 8, and FIG. 4 is a circuit diagram illustrating an equivalent circuit viewed from an output end of the resistance type D/A converter 8. As illustrated in FIG. 3, in the resistance type D/A converter 8, a conductance to the output end on the reference voltage V_{REF} side can be denoted by Gx, and a conductance to the output end on an installation side can be denoted by G(1−x). At this time, the output resistance R_{L} is represented by the following expression 3 and is constant.

#1 (where, 0<x<1) [Expression 3]

Further, the output voltage Vₒᵤₜ is represented by the following expression 4, and is proportional to x.

Vₒᵤₜ=V_{REF}·x [Expression 4]

Accordingly, as illustrated in FIG. 4, the output voltage Vₒᵤₜ can be varied while the output resistance R_{L} is constant. Further, a current I flowing through a voltage source is represented by the following expression 5.

### [Expression 5]

Accordingly, a power consumption Pc is represented by the following expression 6.

### [Expression 6]

As a result, the current flowing through the resistance type D/A converter 8 becomes maximum at x=0.5, and the maximum current becomes ¼ of the current of the current type D/A converter represented by the above-described expression 1. Since the D/A converter used for the image sensor generates the ramp wave between zero to the reference voltage V_{REF}, an average current I_{AVE} is determined from the following expression 7.

### [Expression 7]

Accordingly, the current consumption of the resistance type D/A converter that essentially generates the ramp wave is small like ⅙ of the current consumption of the current type D/A converter. Further, in the case of the current type D/A converter, a power supply voltage V_{DD} is higher by about 0.6 V than the reference voltage V_{REF}. Therefore, when the reference voltage V_{REF} is set to 1.2 V and the power supply voltage V_{DD} is set to 1.8 V, a power consumption ratio is calculated from the following expression 8.

### [Expression 8]

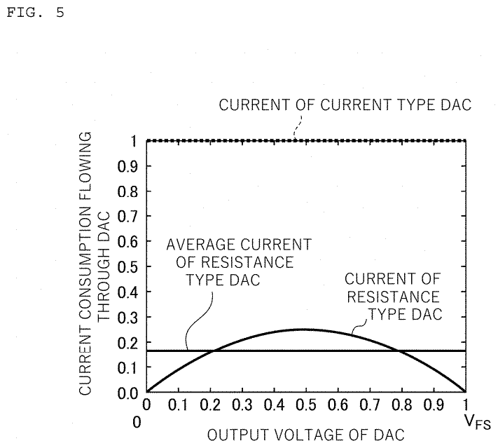

FIG. 5 is a graph illustrating the current consumption of the current type D/A converter and the current consumption and the average current consumption of the resistance type D/A converter, to the output voltage of the D/A converter. As illustrated in FIG. 5 and the expression 8, using the resistance type D/A converter makes it possible to reduce the power consumption to 1/9 of the power consumption of the current type D/A converter even at the same output resistance.

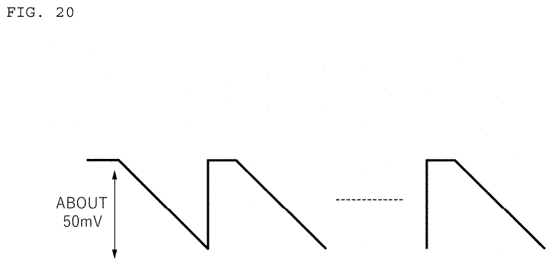

In the CMOS image sensor, in order to capture an image of a dark scene with high quality, only a signal of about 0 mV to about 50 mV as illustrated in FIG. 20 is converted, and in some cases, to reduce noise, a plurality of times of sweeping by the ramp wave is performed and the signal is converted a number of times to determine an average value. In this case, when the amplitude is regarded as β times of a full scale, the current consumption of the resistance type D/A converter is represented by the following expression 9.

### [Expression 9]

In the above-described expression 9, for example, when β is set to 0.05, β/2 is 0.025. The average current becomes extremely small current consumption that is 0.15 times of the current, described in the above-described expression 7, when full scale sweeping is performed.

In contrast, in the case of the current type D/A converter, the current is constant irrespective of the sweeping level. Therefore, such reduction of the current consumption is not performed. Accordingly, using the resistance type D/A converter for the CMOS image sensor is extremely beneficial in terms of reduction of the power consumption. Depending on cases, the D/A converter that sweeps partial voltage illustrated in FIG. 20 is provided instead of the D/A converter that performs full-scale sweeping; however, even when such a D/A converter is provided, using the resistance type D/A converter makes it possible to effectively suppress increase of the power consumption.

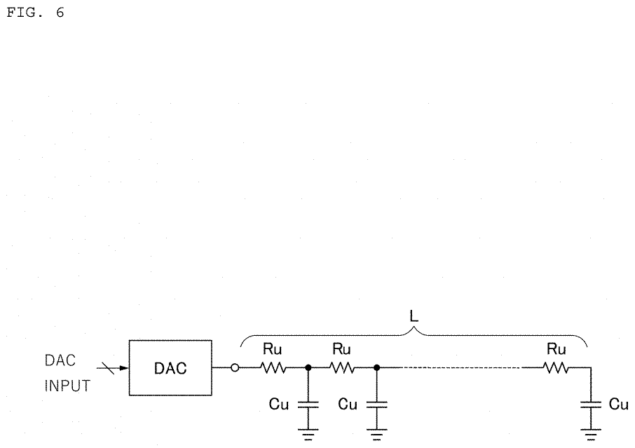

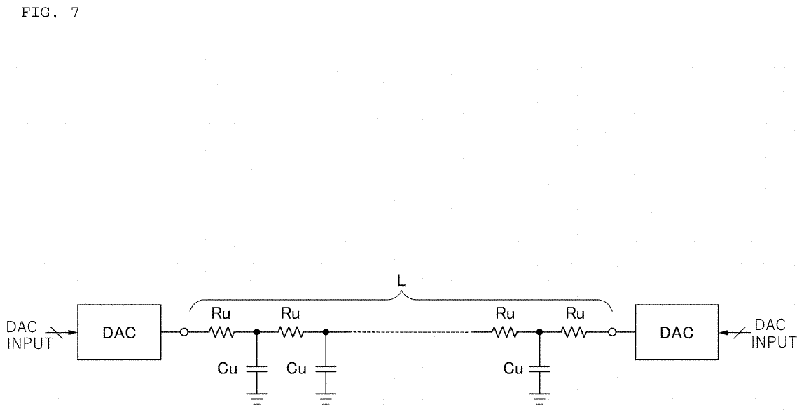

As illustrated in FIG. 15, in the CMOS image sensor, the output of the D/A converter is supplied to a number of comparators spatially distributed. FIG. 6 is a circuit diagram illustrating a D/A converter generating a ramp wave and a distributed RC circuit serving as a load. To be precise, a load circuit is an RC distributed constant circuit in which resistances and capacities are distributed as illustrated in FIG. 6. Therefore, a signal is delayed, and reduction of an amplitude occurs at a drive end of the D/A converter and an open end. At this time, when a resistance per unit length is denoted by Rᵤ, a capacity is denoted by Cᵤ, and a length is denoted by L, a standard time constant τ of the RC distributed constant circuit is represented by the following expression 10.

### [Expression 10]

Influence is larger as the standard time constant τ is larger. FIG. 7 is a circuit diagram illustrating the distributed RC circuit and the D/A converters driving the distributed RC circuit from both sides, in the image sensor according to the present embodiment. In the image sensor 10 according to the present embodiment, the ramp waves may be supplied to the comparator from both sides as illustrated in FIG. 7. As a result, the length L of the RC distributed constant circuit for each of the D/A converter is equivalently ½. Therefore, the time constant is reduced to ¼, and the influence thereof can be reduced. As a result, it is possible to realize A/D conversion with higher accuracy and high-speed A/D conversion. Further, the load capacity of each of the D/A converter is equivalently ½, and the entire power consumption is hardly increased because the output resistance may be twice.

As described in detail above, the image sensor according to the present embodiment includes: the resistance type D/A converter that is configured by connecting, in parallel to one another, the unit circuits each including the resistor connected to the output end of the CMOS inverter, and generates the ramp wave; and the A/D conversion unit including the plurality of A/D converters converting signals from the pixels into digital signals by comparing the signals from the pixels with the ramp wave. Therefore, the image sensor according to the present embodiment can considerably reduce the power consumption as compared with the conventional CMOS image sensor.

### Second Embodiment

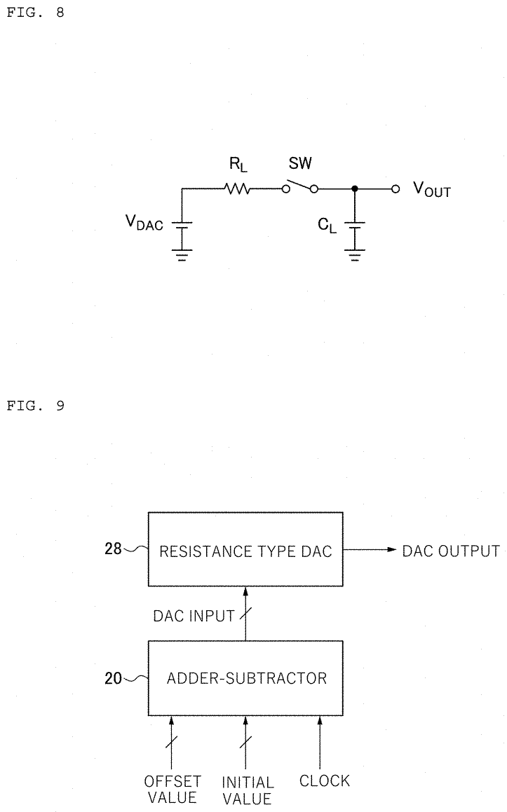

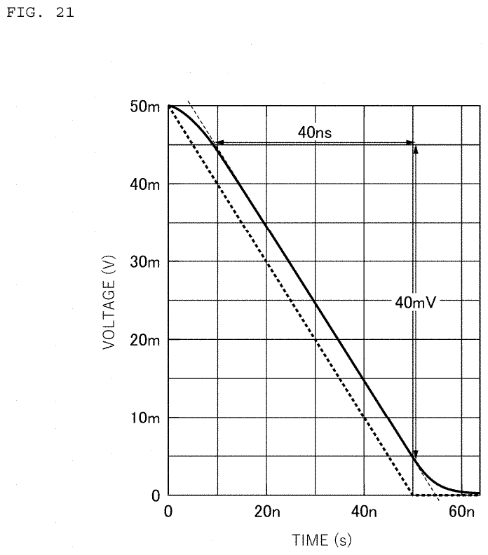

Next, an image sensor according to a second embodiment of the present invention is described. FIG. 8 is a circuit diagram illustrating an equivalent circuit of the D/A converter considering a load. One of issues of the D/A converter provided in the CMOS image sensor is generation of the ramp wave at high speed. As illustrated in FIG. 21, in the D/A converter, an effectively-usable time range is limited by distortion of the waveform. Therefore, high-speed conversion is difficult. The cause thereof is presence of a capacity C_{L} in the circuit as illustrated in FIG. 8. A response when the ramp wave is input to such a circuit is represented by the following expression 11.

V_{DAC}(t)=kt [Expression 11]

Further, when Laplace transform is performed on the voltage Vₒᵤₜ in the load circuit that receives the waveform represented by the above-described expression 11, the following expression 12 is obtained.

#1 (where, τ=R_{L}C_{L}) [Expression 12]

Further, when inverse Laplace transform is performed on the above-described expression 12 to obtain a time response, the following expression 13 is obtained.

### [Expression 13]

In the above-described expression 13, a first term represents an ideal ramp wave, and a second term represents a voltage error. The voltage error represents a response of a step wave. Therefore, the offset voltage V_{off} is represented by the following expression 14.

V_{off}=kτ [Expression 14]

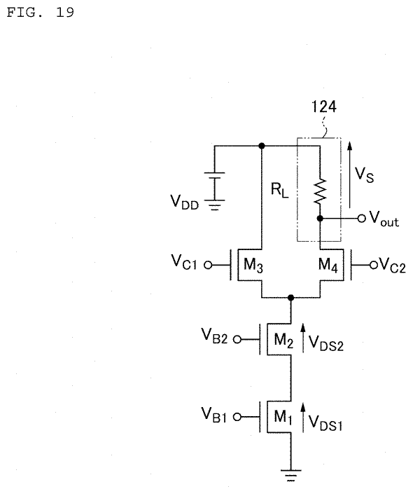

Therefore, it is found that application of the offset voltage V_{off} represented by the above-described expression, when the output voltage of the D/A converter being varied, makes it possible to cancel the variation of the output voltage. FIG. 9 is a block diagram illustrating a configuration of a resistance type D/A converter in the image sensor according to the present embodiment. When the D/A converter generates the ramp wave, the image sensor according to the present embodiment does not perform addition or subtraction of a clock to/from a set initial value but performs addition or subtraction of a clock after adding a correction value (offset value) corresponding to the offset voltage V_{off} represented by the above-described expression 14 to the set initial value, as illustrated in FIG. 19. This makes it possible to solve the issue of generation of the ramp wave at high speed.

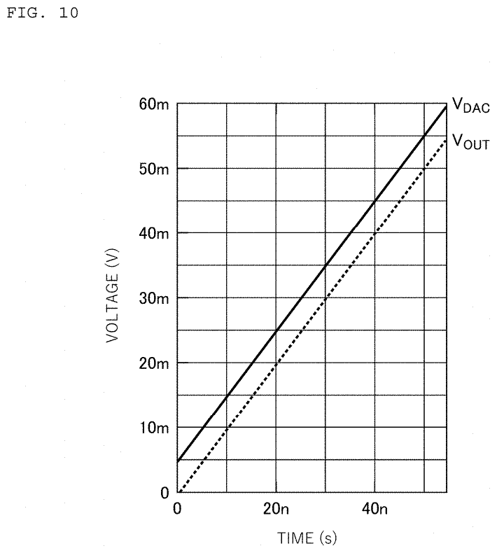

FIG. 10 is a waveform diagram illustrating an output voltage V_{DAC} of a resistance type D/A converter 28 illustrated in FIG. 9 and the voltage Vₒᵤₜ of the load circuit having the capacity, in a case where a prescribed offset value is added when the time rate of change of the voltage of the ramp wave is varied. It is found from FIG. 10 that an accurate ramp wave can be generated by adding the correction value corresponding to the offset voltage V_{off} when the rate of change of the voltage over time is varied.

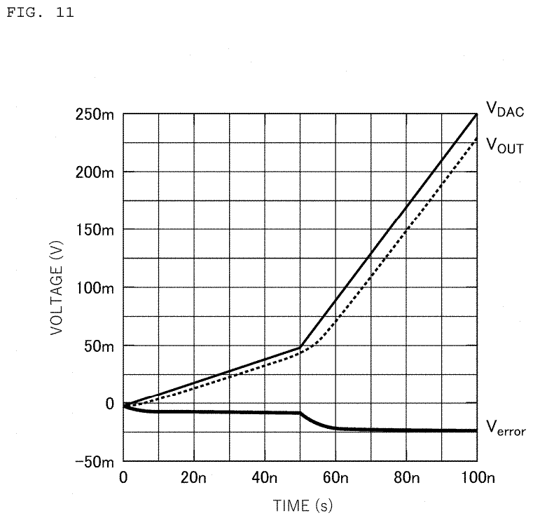

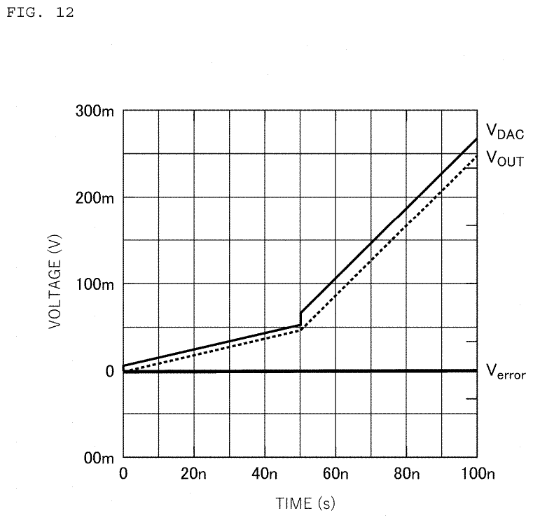

Further, even in a case where a time rate of change of the ramp wave is varied a plurality of times with time, it is possible to generate the accurate ramp wave by varying the offset value based on change of the time rate of change of the ramp wave. FIG. 11 is a waveform diagram illustrating the output voltage V_{DAC} of the resistance type D/A converter and the voltage Vₒᵤₜ of the load circuit having the capacity, in a case where no correction value is added when the time rate of change is varied twice. As illustrated in FIG. 11, when the ramp wave is generated at 0 s, the time rate of change is varied at this time and an error Vₑᵣᵣₒᵣ is generated, which causes waveform distortion. When the time rate of change is quadrupled at 50 ns, a large error Vₑᵣᵣₒᵣ is generated, and a large waveform distortion is generated.

FIG. 12 is a waveform diagram illustrating the output voltage V_{DAC} of the D/A converter and the voltage Vₒᵤₜ of the load circuit having the capacity, in a case where the time rate of change of the ramp wave is varied a plurality of times with time and the offset value is accordingly varied when the time rate of change of the voltage of the ramp wave is varied. As illustrated in FIG. 12, when the ramp wave is generated at 0 s, the time rate of change is varied at this time, and the error Vₑᵣᵣₒᵣ is zero. When the time rate of change is quadrupled at 50 ns, the error Vₑᵣᵣₒᵣ can be made zero by varying the correction value, and the waveform distortion is not generated. Therefore, it is found that the method can effectively suppress the waveform distortion.

As described above, in a case where the ramp wave, the time rate of change of which is varied a plurality of times with the time, is used for the CMOS image sensor, it is possible to reduce the conversion time and to increase the frame rate by increasing the time rate of change of the ramp wave after the signal intensity is increased to a certain degree. This makes it possible to advantageously realize low power consumption by acceleration or conversion time reduction.

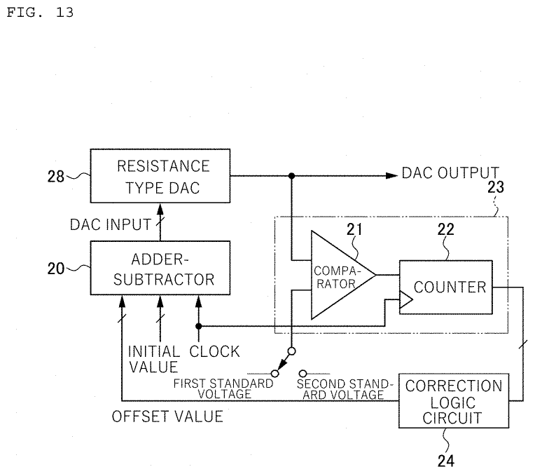

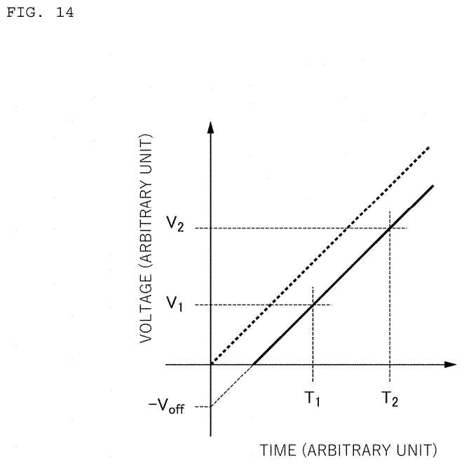

In contrast, in a case where the above-described method is applied to the actual image sensor, a calibration circuit is necessary because it is difficult to previously determine the time constant of the load. FIG. 13 is a diagram illustrating a configuration of the calibration circuit, and FIG. 14 is a diagram illustrating relationship of an output voltage, a standard voltage, and a time in the calibration circuit. As illustrated in FIG. 13, the calibration circuit includes an output voltage of the resistance type D/A converter 28 appearing in a load circuit, two types of standard voltages (first standard voltage and second standard voltage), a correction A/D converter 23, and a correction logic circuit 24.

In FIG. 14, the ideal ramp wave is illustrated by a dashed line. When a voltage at a time point 0 is set to zero, an actual response is shifted due to an RC time constant as illustrated by a solid line in FIG. 14. Although the voltage is positive, a negative voltage is illustrated by an auxiliary dashed line. In such a state, when a voltage at a time point T₁ is set to V₁ and a voltage at a time point T₂ is set to V₂, the offset voltage V_{off} is determined from the following expression 15.

### [Expression 15]

Therefore, in the image sensor according to the present embodiment, it is sufficient to add the offset voltage V_{off} calculated by the above-described expression 15, as the correction value. More specifically, as illustrated in FIG. 13, the output of the resistance type D/A converter 28 is compared with the standards voltages V₁ and V₂, and the time points T₁ and T₂ are determined from counter values by using a time-domain correction A/D converter 23 that includes a comparator 21 outputting time information on the comparison and a counter 22. Further, the correction value is calculated from the above-described expression 15, and a necessary offset voltage (offset value) is output from the correction logic circuit 24.

It goes without saying that the offset voltage is preferably asymptotically brought close to the ideal value by supplying the correction value determined by the correction logic circuit 24 to an adder-subtractor 20 outputting an input value for the resistance type D/A converter 28, again comparing the output of the resistance type D/A converter 28 with the standard voltages V₁ and V₂, and determining the time points T₁ and T₂ from the counter values by using the correction A/D converter 23. Further, the correction value can be calculated from one voltage and one time point without using the two voltages and the two time points; however, in this case, an error is easily generated due to the offset voltage of the comparator and delay. Therefore, the method using the two voltages and the two time points can calculate the accurate offset voltage.

As described above, the resistance type D/A converter in the image sensor according to the present embodiment can reduce the waveform distortion of the ramp wave by adding the prescribed offset value when the time rate of change of the voltage of the ramp wave is varied, and can realize the A/D conversion at high speed with high accuracy. Note that configurations and effects other than the above-described configurations and effects in the image sensor according to the present embodiment are similar to the configurations and effects in the above-described first embodiment.

In the above-described first and second embodiments, the CMOS image sensor is described as an example; however, the present invention is not limited thereto. The above-described first and second embodiments are applicable to a two-dimensional image sensor for other applications. Further, the image sensor according to the present invention includes an infrared sensor, a terahertz sensor, a magnetic sensor, a pressure sensor, and the like.

### REFERENCE SIGNS LIST

1, 101 Pixel unit
1a, 101a Pixel
2, 102 Vertical control circuit
3, 103 Row access line
4, 104 Pixel signal line
5, 105 A/D conversion unit
5a Integral type A/D conversion device
6, 106 Horizontal control circuit
7 Entire control circuit
8, 28 Resistance type D/A converter
9 Clock circuit
10, 100 CMOS image sensor
20 Adder-subtractor
21, 111 Comparator
22, 112 Counter
23 Correction A/D converter
24 Correction logic circuit
81 Inverter
82 Decoder circuit
121 Decoder
122 Current source
123 Switch
124 Load resistor
125 Power supply

1. An image sensor, comprising:
a pixel unit including a plurality of pixels two-dimensionally arranged in a row direction and a column direction, each of the plurality of pixels including a sensor element configured to detect a physical amount existing in nature and to convert the physical amount into an electric signal;
a resistance type digital-to-analog converter including a plurality of unit circuits connected in parallel to one another and configured to generate a ramp wave, each of the plurality of unit circuits including a resistor connected to an output end of a CMOS inverter; and
an analog-to-digital conversion unit including a plurality of integral type analog-to-digital converters and configured to convert signals from the pixels into digital signals by comparing the signals from the pixels with the ramp wave, wherein
when a time rate of change of a voltage of the ramp wave is varied, a prescribed offset value is input to the resistance type digital-to-analog converter.

2. The image sensor according to claim 1, wherein the resistance type digital-to-analog converter includes a high-order bit conversion unit and a low-order bit conversion unit, the high-order bit conversion unit including the unit circuits connected in parallel to one another for number corresponding to high-order bits, each of the unit circuits of the high-order bit conversion unit including the resistor having one end connected to the output end of the CMOS inverter and another end connected to an output end of the resistance type digital-to-analog converter, the low-order bit conversion unit including the unit circuits connected in parallel to one another for number corresponding to low-order bits, each of the unit circuits of the low-order bit conversion unit including the resistor having one end connected to the output end of the CMOS inverter and another end connected to a resistor between terminals.

3. (canceled)

4. The image sensor according to claim 1, wherein the resistance type digital-to-analog converter is provided at each of both ends of a signal line supplying the ramp wave to the analog-to-digital conversion unit.

5. (canceled)

6. The image sensor according to claim 1, wherein the time rate of change of the voltage of the ramp wave is varied a plurality of times with time, and the offset value is also varied based on variation of the time rate of change.

7. The image sensor according to claim 1, wherein the offset value is calculated based on a first standard voltage, a second standard voltage different from the first standard voltage, a first time point when the voltage of the ramp wave becomes the first standard voltage, and a second time point when the voltage of the ramp wave becomes the second standard voltage.
